(19) United States
(12) Patent Application Publication
(10) Pub. No.: US 2007/0126083 A1
(43) Pub. Date: Jun. 7, 2007

(54) SEMICONDUCTOR DEVICE

(76) Inventors: Kentaro SUZUKI, Tokyo (JP); Ikuya Ono, Tokyo (JP); Tadatoshi Danno, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/566,963

(22) Filed: Dec. 5, 2006

(30) Foreign Application Priority Data
Dec. 6, 2005 (JP) 2005-351846

(51) Int. Cl. H01L 29/93

(52) U.S. Cl. 257/595; 257/E29.344; 257/602

(57) ABSTRACT

The semiconductor device provided assures stable communication processes. For example, a varactor diode for adjusting the reference frequency is comprised within a digital crystal-controlled oscillating circuit provided as an internal circuit of the front-end circuit for generating the reference oscillation signal of a PLL circuit or the like. The varactor diode is formed to a semiconductor layer DF of the so-called SOI structure in the structure where an embedded insulating layer, a n⁻type semiconductor region, a p type semiconductor region, and a n⁺ type semiconductor region are formed in this sequence and the n⁺ type semiconductor region is connected to a cathode node which becomes the frequency adjusting node. Moreover, a p⁺ type semiconductor region connected to the p type semiconductor region is formed in both sides of the n⁺ type semiconductor region, and this p⁺ type semiconductor region is connected to an anode node to which the ground voltage is applied. Accordingly, noise transferred to a frequency adjusting node via the embedded insulating layer from a semiconductor substrate can be reduced.

### CROSS-REFERENCE TO RELATED APPLICATION

The present application claims priority from Japanese patent application No. 2005-351846 filed on Dec. 6, 2005, the content of which is hereby incorporated by reference into this application.

### BACKGROUND OF THE INVENTION

The present invention relates to a semiconductor device and particularly to a technology which may be applied effectively to a semiconductor device used to a mobile phone system to conduct up-conversion and down-conversion.

For example, the patent document 1 discloses the technology to individually provide the ground of each circuit in a structure where a semiconductor chip including a plurality of circuits is mounted to a package such as QFN (Quad Flat Non-leaded package) corresponding to down-bonding. In more concrete, the patent document 1 explained above discloses a structure that a ground pad of a low-noise amplifier belonging to the receiving system is bonded in direct to an external lead for a semiconductor chip to execute signal processes of the transmitting and receiving systems such as modulation and demodulation in the radio communication. Thereby, diffusion of ground noise toward the low-noise amplifier can be prevented. Moreover, the patent document 1 discloses a structure that the rear surface of a semiconductor chip is connected to a die pad using a conductive bonding agent, in addition to the bonding explained above, by utilizing the semiconductor chip provided with the so-called SOI (Silicon on Insulator) structure.

[Patent document 1] Internationally published Pamphlet: 03/94232

### SUMMARY OF THE INVENTION

A radio communication system represented by a mobile phone system is generally provided with an up-conversion function and a down-conversion function to synthesize a baseband signal and a radio frequency local oscillation signal. The local oscillation signal is usually generated using a PLL (Phase Locked Loop) circuit on the basis of the reference oscillation signal, for example, of 26 MHz or the like generated by a crystal-controlled oscillation circuit. Accordingly, it is necessary for accurate up-conversion (and modulation) and down-conversion (and demodulation) to stably generate the reference oscillation signal in higher frequency accuracy.

Meanwhile, the up- and down-conversion functions including such PLL circuit and crystal-controlled oscillating circuit are often realized with only one semiconductor chip called a front-end IC. In this case, a crystal-controlled vibrator required in the crystal-controlled oscillating circuit is provided as a component provided externally to the semiconductor chip. However, if the crystal-controlled vibrator has fluctuation or the like in manufacturing process, such highly accurate frequency cannot be realized. Accordingly, the reference oscillation signal is corrected under the so-called AFC (Automatic Frequency Correction) control using a variable capacitance element such as a varactor diode (or a varicap diode) in addition to the crystal-controlled vibrator.

AFC means the control for setting the frequency of the reference oscillation signal of a communication terminal in order to eliminate an frequency error to data signal including the carrier transmitted toward the communication terminal (such as a mobile phone or the like) from a base station. In more concrete, the control is executed to adjust a voltage of variable capacitance element (namely, the frequency of the reference oscillation signal) to set phases of the I signal and Q signal to the desired conditions by extracting these I and Q signals as the baseband signals and quadrature signals, for example, through demodulation of the data signal from the base station.

The AFC control explained above is sequentially executed, for example, when a communication terminal is in the idle state (for example, a mobile phone does not executing communication and the position information is exchanged with a base station). Therefore, frequency of the reference oscillation signal may be kept in higher accuracy for the frequency in the base station side. However, the inventors of the present invention have proved through investigation that it is not always possible to stably generate highly accurate frequency of the reference oscillation signal depending on a structure of the front-end IC explained above.

FIG. 10 is a cross-sectional view of the essential portion showing an example of structure of a semiconductor chip used in a semiconductor device discussed as a precondition for achieving the present invention. FIGS. 11A and 11B show examples of external shapes of a package to mount a semiconductor chip, wherein FIG. 11A is a cross-sectional view and FIG. 11B is a plan view.

The semiconductor chip shown in FIG. 10 is provided with a so-called SOI structure where an embedded insulating layer IS1 (SiO₂) is formed on a semiconductor substrate (supporting substrate) SUB and moreover a semiconductor layer DF is formed on the IS1. On this semiconductor layer DF, a varactor diode PN_VD4 used in the crystal-controlled oscillating circuit explained above is formed, for example, in addition to the PMOS transistor PMOS_TR, NMOS transistor NMOS_TR or NPN bipolar transistor NPN_TR used as the element circuits such as up- and down-converter circuits and PLL circuit. Transistor and varactor diode PN_VD4 are respectively separated by the embedded insulating layer IS1 and a trench isolation insulating layer IS2 (SiO₂) formed to reach the IS1 from the main surface of the semiconductor layer DF.

On the semiconductor layer DF of varactor diode PN_VD4, a n⁺⁺ type semiconductor region (N⁺⁺) and a n type semiconductor region (N) are sequentially formed toward the main surface of the DF from the embedded insulating layer IS1. Moreover, a p⁺ type semiconductor region (P⁺) is formed within the n type semiconductor region (N) and this region is connected to a metal wiring layer Ml as an anode node AD via a barrier layer (CoSi₂) and a contact layer CNT. Meanwhile, a n⁺ type semiconductor region (N⁺) is formed, in one side of the p⁺ type semiconductor region (P⁺), holding an insulating layer IS3 formed to reach the n type semiconductor region (N) from the main surface of the DF. This n⁺ type semiconductor region (N⁺) is formed within the n type and n⁺⁺ type semiconductor regions (N/N⁺⁺) and is connected to the metal wiring layer Ml as a cathode node CD via the barrier layer (CoSi₂) and contact layer CNT.

Such semiconductor chip can realize a high packing density and therefore this semiconductor chip is mounted to a BGA (Ball Grid Array) package shown in FIGS. 11A and 11B. In such FIGS. 11A and 11B, a semiconductor chip DIE is mounted via an insulating paste material NC_PST on the front surface of the wiring substrate SB respectively provided with a wiring pattern MS at the front and rear surfaces. Various kinds of electrode pads provided on the front surface of the semiconductor chip DIE are connected to the wiring pattern MS at the front surface of the wiring substrate SB via bonding wires BW. The wiring pattern MS on the front surface of SB is connected to a wiring pattern MS at the rear surface through a via and is also connected to a solder ball HB via the wiring pattern MS at the rear surface. Here, an insulating paste material is used, because various wiring patterns MS are formed at the front surface region of the wiring substrate SB located just under the semiconductor chip DIE, as shown in FIG. 11B.

Since each transistor and varactor diode PN_VD4 are isolated with the insulating layers IS1, IS2 in the SOI structure shown in FIG. 10, influence of noise can be reduced to a certain degree. However, each transistor constituting the up- and down-converter circuits and PLL circuit or the like often operates with higher frequency in the level of several GHz, for example, during conversation, resulting in very higher noise level. The inventors of the present invention has proved through investigation that a capacitance value of the varactor diode PN_VD4 varies depending on such noise level and thereby the frequency (reference frequency) of the reference oscillation signal becomes unstable. Moreover, the inventors of the present invention have found the fact, as a cause of above phenomenon, that noise diffuses toward the n⁺⁺ type semiconductor region (N⁺⁺) of PN_VD4 of FIG. 10 via the semiconductor substrate SUB from the embedded insulating layer IS1 just under each transistor and thereby a voltage of the cathode node CD for controlling capacitance value of the PN_VD4 is varied.

FIG. 12 is a graph showing result of evaluation for the reference frequency of a crystal-controlled oscillating circuit included in a semiconductor chip under the condition that the semiconductor chip of FIG. 10 is sealed within a package of FIG. 11A. In FIG. 12, temperature is plotted on the horizontal axis, while the absolute value of {(reference frequency during transmission)−(reference frequency during reception)}. on the vertical axis. Moreover, evaluation has been conducted for three kinds (0.1V, 0.9V, 2.4V) of voltages (namely, voltages of the cathode node CD of PN_VD4) for the AFC control. As shown in FIG. 12, an error of about 0.1 ppm (about 2.6 Hz for 26 MHz) is generated in the reference frequencies during transmission and reception as shown in FIG. 12.

Namely, even if the reference frequency is corrected through the AFC control under the idle state, the corrected reference frequency varies when the idle state varies to the transmitting state and receiving state, suggesting that the reference oscillation signal cannot always be generated stably. The assumed reason is that the circuits operating within the semiconductor chip during transmission and reception varies and thereby noise applied to the PN_VD4 also varies respectively. In general, for reliable transmission and reception with the base station, the accuracy within ±0.1 ppm is always requested for the reference frequency without relation to transmission and reception, and more preferably the accuracy within ±0.06 ppm is requested.

Here, it can be considered, in order to solve the problem explained above, to externally provide, for example, a varactor diode PN_VD like a crystal controlled vibrator. However, systems corresponding to different communication systems such as the GSM (Global System for Mobile Communications) system using 880 to 915 MHz band and the DCS (Digital Cellular System) system using 1710 to 1785 MHz are introduced in the mobile phone systems in recent years. Particularly, in this case, considerable increase can be seen in both number of components and component area and thereby it is more and more required to acquire sufficient mounting area of components. It is therefore required to comprise as many components as possible into a semiconductor chip.

Accordingly, it is an object of the present invention to provide a semiconductor device for enabling stable communication process. Moreover, it is also another object of the present invention to provide a semiconductor device for enabling reduction in size of radio communication system. The aforementioned and the other objects and novel features will become apparent from the detailed description of this specification and the accompanying drawings.

The representative inventions among those disclosed in this specification will be briefly described below.

The semiconductor device of the present invention is provided with a semiconductor chip of the so-called SOI structure wherein a first insulating layer is formed on a supporting substrate and a semiconductor layer is formed on the first insulating layer. On this semiconductor layer, a first circuit for generating the reference oscillation signal having the predetermined reference frequency, a second circuit for generating a local oscillation signal having the frequency equal to a constant number times of the reference frequency using this reference oscillation signal, and a frequency converting circuit for synthesizing a transmitting signal or a receiving signal and the local oscillation signal. In the structure explained above, the present invention is characterized in that a varactor diode for adjusting the reference frequency by changing a voltage of the frequency adjusting node for the reference voltage node is formed to the region of the first circuit of the semiconductor layer.

A mobile phone system, for example, in which high density packing of components may be advanced by comprising the varactor diode on the semiconductor chip as explained above can realize reduction in size of system, easier mounting of components and reduction in component inspection cost. Moreover, formation of a plurality of built-in varactor diodes can also realize highly accurate adjustment of the reference frequency.

Moreover, the semiconductor device of the present invention is characterized in that a first semiconductor region of a first conductivity type connected to the frequency adjustment node is formed to the varactor diode of the semiconductor layer explained above and a second semiconductor region of a second conductivity type opposing to the first conductivity type is formed between the first insulating layer explained above and the first semiconductor region. According to the structure explained above, even when noise is generated toward the varactor diode via the supporting substrate and the first insulating layer, for example, from the second circuit and frequency converting circuit or the like explained above, the reference frequency can be stabilized, because such noise is alleviated in the second semiconductor region until the noise is transferred to the frequency adjustment node.

As a more concrete structure, several ideas may be thought, with inclusion, for example, of formation of a third semiconductor region of the first conductivity type on the first insulating layer, formation of the second semiconductor region explained above on the third semiconductor region, and formation of the first semiconductor region explained above on the second semiconductor region. In this case, the first semiconductor region, for example, becomes a cathode node, the second semiconductor region becomes an anode node, and this anode node is connected to the reference voltage node such as the ground voltage or the like. Moreover, the third semiconductor region is preferably formed in the impurity density lower than that of the first semiconductor region. For example, when the first semiconductor region is of the n⁺ type, the third semiconductor region becomes n⁻ type.

When the structure explained above employed, since noise explained above is reduced by a higher resistance of the third semiconductor region and by a junction capacitance between the third semiconductor region and the second semiconductor region and moreover the noise is shielded with the second semiconductor region, noise is almost not transferred to the first semiconductor region corresponding to the frequency adjustment node. Therefore, the reference frequency can always be maintained in the stable state and thereby the communication process such as up-conversion and down-conversion (modulation and demodulation) can always be conducted stably.

In addition, the semiconductor device of the present invention is characterized in that the reference voltage nodes connected to the second semiconductor region are allocated in both sides of the frequency adjustment node connected to the fist semiconductor region when the varactor diode of the semiconductor layer explained above is viewed as a plan view from the side of the main surface. When such structure is employed, the reference frequency can be stabilized because the frequency adjustment node is shielded by the reference voltage node for the noise transferred in lateral direction, for example, with the wiring layer on the semiconductor chip.

Moreover, in the semiconductor device of the present invention, the semiconductor chip explained above is mounted, for example, to a package such as BGA and the rear surface of semiconductor chip (rear surface of supporting substrate) may be fixed to the ground voltage. In more concrete, a wiring pattern for ground voltage connected to an external terminal to be grounded is provided, for example, on the front surface of the wiring substrate such as BGA and the rear surface of the supporting substrate is connected to this wiring pattern using a conductive paste. Thereby, noise via the supporting substrate can also be reduced and stable communication process can be realized.

Accordingly, in brief explanation of the effects obtained with the representative invention among those disclosed in this specification, the stable communication process can be realized.

### BRIEF DESCRIPTION OF THE DRAWINGS

FIG. 1 is a block diagram showing an example of structure of a radio communication system to which a semiconductor device of a first embodiment of the present invention is applied.

FIG. 2 is a schematic diagram showing an example of arrangement structure of circuits in the semiconductor device of FIG. 1.

FIG. 3 is a schematic diagram showing an example of structure of a digital crystal-controlled oscillating circuit within a front-end circuit of the radio communication system of FIG. 1.

FIGS. 4A and 4B are diagrams for explaining an example of detail operations of the digital crystal-controlled oscillating circuit of FIG. 3, in which FIG. 4A is a diagram showing a characteristic example of a varactor diode, while FIG. 4B is a diagram showing an example of the method for adjusting oscillation frequency using the varactor diode.

FIGS. 5A and 5B are diagrams for showing an example of structure of the varactor diode in the digital crystal-controlled oscillating circuit of FIG. 3, in which FIG. 5A is a plan view and FIG. 5B is a cross-sectional view along the line A-A′ of FIG. 5A.

FIG. 6 is a graph showing the result of evaluation of the reference frequency of the digital crystal-controlled oscillating circuit under the condition that the front end circuit comprising the varactor diode of FIG. 5A is sealed in the package of FIG. 11A.

FIGS. 7A and 7B are diagrams showing an modification example of the varactor diode of FIG. 5A in the semiconductor device of a second embodiment of the present invention, in which FIG. 7A is a cross-sectional view and FIG. 7B is a graph showing the evaluation result thereof.

FIGS. 8A and 8B are diagrams showing another modification of the varactor diode of FIG. 5A in the semiconductor device of a third embodiment of the present invention, in which FIG. 8A is a cross-sectional view and FIG. 8B is a graph showing the evaluation result thereof.

FIGS. 9A and 9B are diagrams showing an example of the external shape of a package of the semiconductor device of a fourth embodiment of the present invention, in which FIG. 9A is a cross-sectional view and FIG. 9B is a plan view.

FIG. 10 is a cross-sectional view of the essential portion of the semiconductor device discussed as a preamble of the present invention showing an example of structure of a semiconductor chip of the same semiconductor device.

FIGS. 11A and 11B are diagrams showing an example of external shape of the package where the semiconductor chip of FIG. 10 is mounted in which FIG. 11A is a cross-sectional view and FIG. 11B is a plan view.

FIG. 12 is a graph showing result of evaluation of the reference frequency of the crystal-controlled oscillating circuit included in the semiconductor chip under the condition that the semiconductor chip of FIG. 10 is sealed within the package of FIG. 11.

### DETAILED DESCRIPTION OF THE PREFERRED EMBODIMENTS

The preferred embodiments of the present invention will be explained below with reference to the accompanying drawings. The like elements are designated with the like reference numerals throughout the accompanying drawings and the like explanation will not be repeated. In the following embodiments, explanation will be made as required through division into a plurality of sections or into respective embodiments. However, unless otherwise specified particularly, such explanations are related with each other, and one is in the relationship such as modification example, detailed or complementary explanation or the like of the other.

Moreover, when explanation refers to the number of elements (including quantity, numerical values, amount and range or the like) in the following preferred embodiments, the explanation is not restricted only to the specified values, unless otherwise specified particularly or clearly restricted to the particular values in the principle and such value may be equal to the particular value or higher or lower. In addition, the structural elements (including element steps or the like) are apparently not always essential in the following embodiments, unless otherwise specified clearly or essential apparently in the principle. Similarly, when explanation refers to shape of structural elements or the like and positional relationship thereof in the following preferred embodiments, those approximated to or similar to such shape and positional relationship are essentially included, unless otherwise specified clearly and to be apparently considered unlike in the principle. This is also applied to numerical values and ranges thereof.

### First Embodiment

A semiconductor device shown in the first embodiment of the present invention is characterized, for example, in a front-end circuit and is mainly characterized, although explained later in detail, in a structure of a varactor diode included in such front-end circuit.

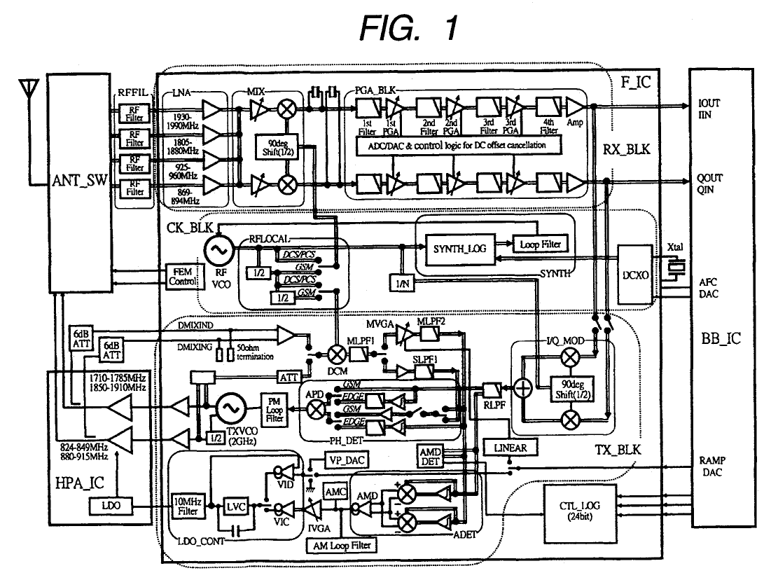

FIG. 1 is a block diagram showing an example of structure of a radio communication system to which a semiconductor device of the first embodiment of the present invention is applied. The radio communication system of FIG. 1 is constituted of a switch ANT_SW for switching connection of antenna ANT in accordance with transmission and reception, a radio-frequency filter RFFIL for removing unwanted wave from the receiving signal, a high frequency power amplifier HPA_IC for amplifying the transmitting signal, an front-end circuit F_IC for demodulating the receiving signal and modulating the transmitting signal, and a baseband circuit BB_IC. Here, the front-end circuit (semiconductor device) F_IC is formed in one semiconductor chip and is then packaged, for example, in BGA or the like. Moreover, the HPA_IC and BB_IC are also formed by individual semiconductor chips and are packaged respectively. Each packaged IC is mounted on one dielectric material substrate including the switch ANT_SW.

Although not restricted particularly, the front-end circuit F_IC is designed, for example, corresponding to four communication systems of GSM850 (transmitting/receiving band: 824 to 894 MHz), GSM900 (880 to 960 MHz), DCS1880 (1710 to 1880 MHz) and PCS1900 (1850 to 1990 MHz). For kinds of filters are provided respectively corresponding to four communication systems within the radio frequency filter RFFIL and the receiving signal from the ANT is classified into the frequency bands corresponding to four communication systems with the RFFIL and is then outputted to the F_IC. The front-end circuit F_IC is roughly classified into a receiving system block RX_BLK, a transmitting system block TX_BLK, a clock system block CK_BLK for supplying various oscillation signals to these blocks, and a control circuit CTL_LOG for controlling the total circuit.

The clock system block CK_BLK is constituted of a digital crsystal-controlled oscillating circuit DCXO for generating the reference oscillation signal, a radio frequency oscillating circuit RFVCO, a synthesizer circuit SYNTH, and a radio frequency dividing circuit RFLOCAL or the like. The DCXO generates, although details will be explained later, the reference oscillation signal, for example, of 26 MHz or 13 MHz and then outputs this signal to the synthesizer circuit SYNTH. The SYNTH includes a synthesizer logic SYNTH_LOG for dividing the oscillation signal from the RFVCO with the preset ratio and comparing the phase of this signal with the phase of the reference oscillation signal and a loop filter for supplying the voltage to the RFVCO in accordance with such phase comparison result in order to control the frequency of the RFVCO. Namely, these elements form a PLL circuit. The radio frequency dividing circuit RFLOCAL divides the oscillation signal from the RFVCO in accordance with each communication system and supplies the divided signals to the transmitting system block TX_BLK and the receiving system block RX_BLK.

The receiving system block RX_BLK is constituted of a low-noise amplifier LNA for amplifying the receiving signal, a mixer MIX for down-converting (frequency converting) the amplified signal and then demodulating the same signal, and a high gain amplifier PGA_BLK for amplifying an output signal of the mixer MIX and then providing an output to the baseband circuit BB_IC. The mixer MIX generates quadrature signals including a phase difference of 90 degrees from the output signal of the radio frequency dividing circuit RFLOCAL and generating the I signal and Q signal by synthesizing the quadrature signals and the receiving signal amplified with the LNA. The high gain amplifier PGA_BLK includes a plurality of low-pass filters (first to fourth filters) and gain control amplifiers (first to third PGAs) connected alternately in series, a gain-fixed amplifier Amp connected to the final stage and an offset canceling circuit in order to provide an output to the BB_IC by individually amplifying the I signal and Q signal. The offset canceling circuit controls the DC offset of an output of each gain control amplifier to “0”.

The transmitting system block TX_BLK is constituted of a modulating circuit I/Q_MOD for conducting quadrature modulation with an intermediate frequency to the I signal and Q signal outputted from the baseband circuit BB_IC, a phase loop system circuit for controlling an output radio wave for realizing matching of phase shift with the modulated signal, and an amplitude loop system circuit for controlling an output radio wave for realizing matching of amplitude shift with this modulated signal. The structure explained above is called a polar loop provided for the GMSK modulation including phase shift (for GSM system) and 8-PSK modulation including phase shift and amplitude shift (for EDGE system). The modulating circuit I/Q_MOD inputs the intermediate frequency obtained by dividing the oscillation signal of the RFVCO to the frequency 1/N and generates the quadrature signals including phase shift of 90 degrees from the oscillation signal of this intermediate frequency in order to modulate the quadrature signals with the I/Q signals from the baseband circuit BB_IC. The I and Q signals modulated with the intermediate frequency are once added and are then inputted to a phase loop system circuit and an amplitude loop system circuit.

The phase loop system circuit is constituted of an oscillating circuit for transmission TXVCO, an offset mixer DCM for inputting a feedback signal of the output from the TXVCO, a phase comparing circuit PH_DET for comparing phase of an-output of the DCM with the phase of modulated signal from the I/Q_MOD, and a loop filter for controlling the TXVCO by generating a voltage in accordance with the comparison result. Namely, as an example, when the communication system is GSM900, the RFVCO outputs the oscillation signal, for example, of 3840 MHz and the intermediate frequency such as 80 MHz can be generated by dividing this oscillation signal. Therefore, the I/Q_MOD generates the modulated signal including the carrier of 80 MHz.

On the other hand, the oscillation signal of 3840 MHz from the RFVCO is divided into the frequency of 1/4 with the radio frequency dividing circuit RFLOCAL and this signal is then supplied as the oscillation signal of 960 MHz to one of the offset mixers DCM. To the other DCM, the oscillation signal (frequency: fTX) of the TXVCO is fed back with the loop (sub-loop) connected to the output or with the loop (main-loop) via the high frequency power amplifying circuit HPA_IC and a coupler. When the outputs of the DCM are applied to the low-pass filter, a frequency difference (960 MHz -fTX) can be obtained and thereby the signal corresponding to this frequency difference and the modulated signal of 80 MHz from the I/Q_MOD are compared in the phases with each other. A loop filter (PM Loop Filter) converts a current of the comparison result of the PH_DET into a voltage to control the TXVCO in order to eliminate phase difference. Accordingly, the oscillation signal of the TXVCO changes to the signal of fTX=880 MHz (communication system GSM900) having a constant amplitude which is identical to the signal obtained by up-converting (frequency conversion) the phase shift information of the modulated signal to 880MHz.

The amplitude loop system circuit is constituted of a variable gain amplifying circuit MVGA for amplifying the signal from the main loop via the DCM, an amplitude comparator ADET for comparing an output of the MVGA and the modulated signal, a loop filter and a variable gain amplifying circuit IVGA for inputting the output, and a power controller LDO_CONT for generating a control voltage of the HPA_IC from an output of the IVGA. The MVGA is provided for controlling an output power of the power amplifying circuit HPA_IC and the gain thereof is set via a gain control circuit LINEAR from the baseband circuit BB_IC.

Namely, an antenna output power for transmission must be controlled within the specified range in the system corresponding to the GSM and EDGE. The signal corresponding to the antenna output power is fed back to one input of the amplitude comparator ADET via the main loop (attenuator ATT → offset mixer DCM → MVGA). Here, when the phase loop and amplitude loop are converged to the steady state, a feedback signal from the main loop as the one input of the ADET becomes identical to the modulated signal from the I/Q_MOD as the other input. Accordingly, when the gain of the MVGA is lowered, an output power of the HPA_IC is controlled to become large in order to eliminate an error with the voltage level of the modulated signal. When the gain is increased on the contrary, the output power is controlled to become small.

The amplitude comparator ADET outputs a difference, for example, between a voltage level of the feedback signal from the main loop and a voltage level of the modulated signal as a current signal. This current signal is converted to a voltage of the loop filter (AM Loop Filter) and this voltage controls an output power of the HPA_IC to eliminate an amplitude error in the ADET. Here, an output of the loop filter controls the HPA_IC via the variable gain amplifying circuit IVGA and power controller LDO_CONT. Gain of the IVGA is controlled to obtain a constant value of { (gain of the MVGA)×(gain of IVGA) }. This IVGA is provided to prevent drop of characteristics such as loop band of amplitude loop and phase allowance or the like when the gain of MVGA is varied. The power controller LDO_CONT executes optimum level adjustment for controlling current-voltage conversion and HPA_IC.

The control circuit CTL_LOG is provided, for example, with a control register or the like and this register is set on the basis of the signal from the baseband circuit BB_IC. This control register is provided for setting control information of each circuit and various operation modes (receiving mode, transmitting mode, idle mode, and warm-up mode, etc.). The control circuit CTL_LOG outputs the timing signal to each circuit in accordance with such information and executes the sequence control in accordance with operation modes. Here, the idle mode means the mode where only a part of the circuits operates as in the case of the waiting time and a greater part of circuits including at least the oscillation circuit stops just like the sleeping mode, while the warm-up mode means the mode where the PLL circuit is driven immediately before transmission or reception.

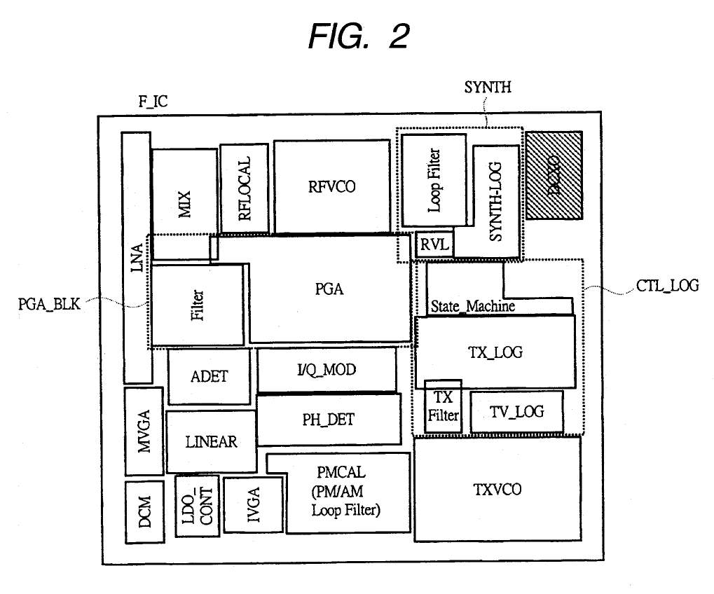

FIG. 2 is a schematic diagram showing an example of arrangement structure of each circuit in the semiconductor device of FIG. 1. The semiconductor device (front-end circuit) F_IC of FIG. 2 includes the digital crystal-controlled oscillating circuit DCXO at the right upper part, the synthesizer circuit SYNTH in the left side thereof, and the control circuit CTL_LOG in the lower side thereof. Moreover, the radio frequency oscillating circuit RFVCO is allocated in the left side of the SYNTH and the radio frequency dividing circuit RFLOCAL I the left side thereof. These elements respectively correspond to the clock system block CK_BLK and the control circuit CTL_LOG of FIG. 1. In the region except for these circuits, the receiving system block RX_BLK is arranged in the upper side and the transmitting system block TX_BLK is arranged in the lower side.

Namely, the low noise amplifier LNA is arranged in the left upper part and the mixer MIX and high gain amplifier PGA_BLK are arranged in the right side thereof. Meanwhile, the offset mixer DCM and the variable gain amplifying circuit MVGA are arranged in the left lower part and the amplitude comparator ADET, gain control circuit LINEAR, power controller LDO_CONT, and variable gain amplifying circuit IVGA are arranged in the right side thereof. Moreover, in the further right side thereof, the modulating circuit I/Q_MOD, phase comparator PH_DET, and loop filter PMCAL are arranged, and the transmitting oscillating circuit TXVCO is arranged adjacently.

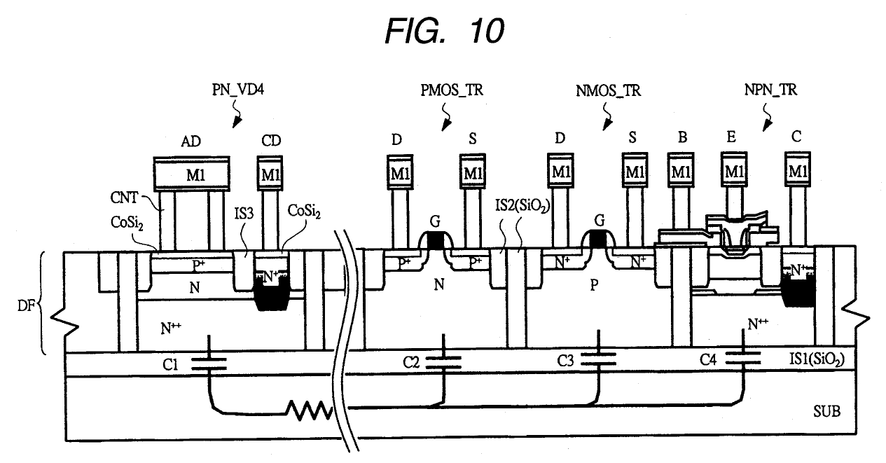

The circuit block explained above is formed on one semiconductor chip, for example, in the SOI structure explained with reference to FIG. 10. Thereby, as will be understood from FIG. 2, noise source position transferred to the DCXO via the semiconductor substrate is different to large extent in the transmitting operation and receiving operation and noise level is also different. Moreover, since the SYNTH and RFVCO allocated near the DCXO operate in the higher frequency and the oscillation frequency is also different a little in the transmitting operation and the receiving operation, noise level applied to the DCXO is also different a little.

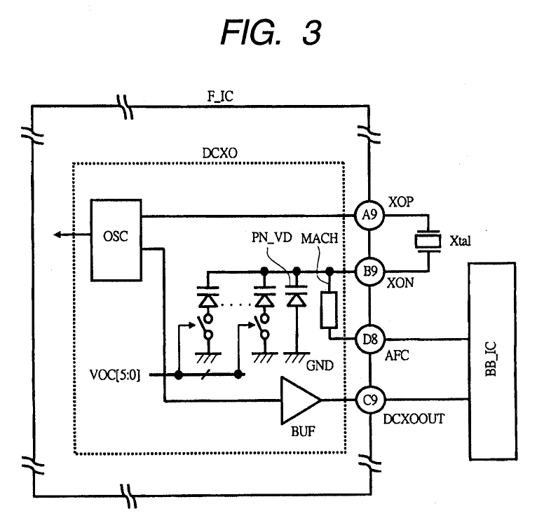

FIG. 3 is a schematic diagram showing an example of structure of the digital crystal-controlled oscillating circuit DCXO in the front-end circuit of the radio communication system of FIG. 1. The digital crystal-controlled oscillating circuit DCXO shown in FIG. 3 is constituted of an oscillator OSC such as Colpitts oscillator, a crystal-controlled vibrator Xtal which is connected at one end thereof to the OSC to determine the oscillation frequency, and a plurality of varactor diodes PN_VD connected to the other terminal of Xtal at the cathode thereof and to the ground voltage GND at the anode thereof for the fine adjustment of oscillation frequency. The OSC and a plurality of varactor diodes PN_VD are formed within the same semiconductor chip and the Xtal is an externally provided component of the semiconductor chip.

To the connecting points (frequency adjusting nodes) of the Xtal and a plurality of varactor diodes PN_VD, the voltage signal is supplied from the baseband circuit BB_IC via the AFC terminal and a matching circuit (resistance or the like) MACH. Accordingly, a capacitance value of the variable capacitance formed of a plurality of varactor diodes PN_VD is controlled and fine adjustment of the oscillation frequency of the OSC is executed. The reference oscillation signal such as 26 MHz or the like generated by such structure is supplied to the synthesizer SYNTH of FIG. 1. Here, the reference oscillation signal can also be outputted to the baseband circuit BB_IC via a buffer BUF.

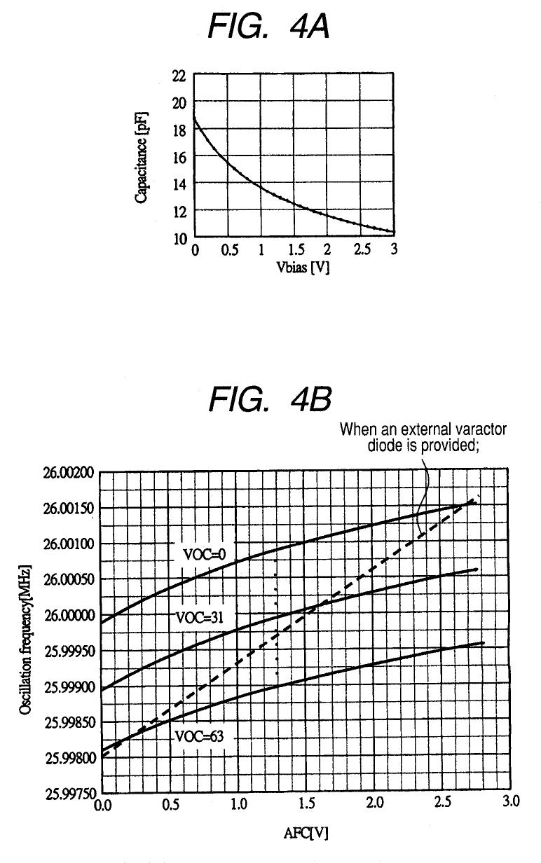

FIGS. 4A and 4B are diagrams for explaining an example of the detailed operations of the digital crystal-controlled oscillating circuit of FIG. 3. FIG. 4A is a diagram showing characteristic example of a varactor diode and FIG. 4B is a diagram showing an example of the oscillation frequency adjusting method using the varactor diode. As shown in FIG. 4A, the varactor diode PN_VD of FIG. 3 has the characteristic of lowering a capacitance value in accordance with rise of a voltage value of the cathode node (AFC terminal). Here, as shown in FIG. 3, the AFC terminal is connected, for example, with seven varactor diodes PN_VD in parallel and it is assumed that six capacitance values of such varactor diodes are weighted by 2N. In this case, total of 64capacitance values may be realized by respectively controlling ON and OFF conditions of the six varactor diodes PN_VD with the control signal VOC [5:0]. The control shown in FIG. 4B can be realized through digital control for selections of 64 capacitance values and through analog control by the AFC control.

FIG. 4B shows changes of frequency of the reference oscillation signal caused by voltage control of the AFC terminal in such a case where the control signal VOC [5:0] is 0 (“000000”), 31 (“011111”), or 63 (“111111”). Moreover, in comparison with above, such frequency change is also shown in the case where the varactor diode is provided as an external component. When the varactor diode is provided as an external component, frequency adjustment may be done in wider frequency range through the voltage control of AFC. However, in this case, stable fine adjustment is difficult, because variation of frequency becomes large for the voltage of AFC as shown in FIG. 4B. Moreover, as is explained above as the problem to be solved by the invention, it is not desirable to provide an external component from the point of view of acquiring the mounting area.

On the other hand, when a varactor diode is provided as a built-in component, since variation of individual capacitance value is small, it is difficult to realize frequency adjustment in the wider frequency range with only one varactor diode. However, frequency adjustment in wider frequency range can be performed, using a plurality of varactor diodes, by realizing the frequency ranges of 64 stages as shown in FIG. 4B. In addition, since frequency variation for the AFC voltage is small in individual frequency ranges, stable fine adjustment is possible.

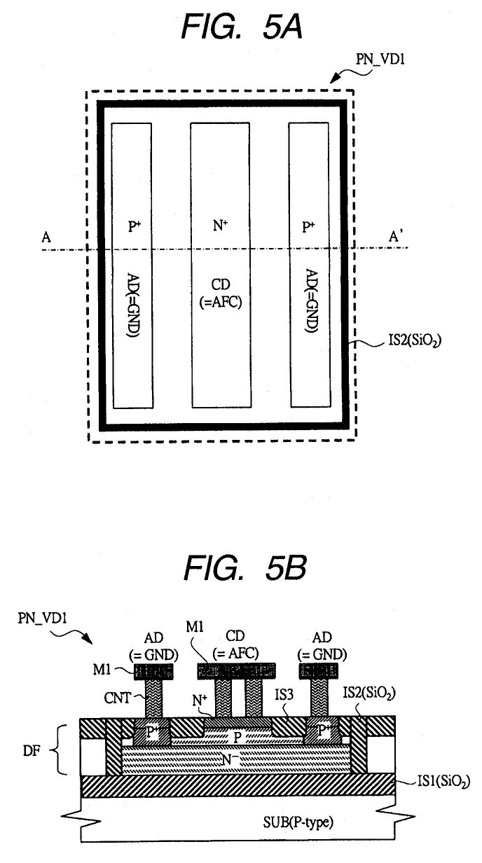

FIGS. 5A and 5B are diagrams showing an example of structure of a varactor diode in the digital crystal-controlled oscillating circuit of FIG. 3. FIG. 5A is a plan view and FIG. 5B is a cross-sectional view along the line A-A′ in FIG. 5A. A structure of this varactor diode is a principal characteristic of this embodiment. Here, a single structure of only one varactor diode PN_VD1 is shown. However, in actual, as shown in FIG. 10, the varactor diode is provided as a part of a semiconductor chip forming the front-end circuit F_IC, wherein the varactor diode PN_VD4 in the conventional structure shown in FIG. 10 is replaced with the varactor diode PN_VD1 of FIG. 5. In addition, as shown in FIG. 3, the number of varactor diodes PN_VD1 is not restricted to only one and a plurality of varactor diodes may be formed.

In FIG. 5A, the principal part of the diffusing layer in the varactor diode PN_VD1 is shown, wherein the p⁺ type semiconductor regions (P⁺) corresponding to the anode node AD are formed in both sides of the n⁺ type semiconductor region (N⁺) corresponding to the cathode node CD. The AFC terminal voltage is applied to the cathode node CD, while the ground voltage GND is applied to the anode node AD. These semiconductor regions are surrounded with a trench isolation insulating film IS2 and thereby the isolated varactor diodes PN_VD1 are formed individually. In this example, the p⁺ type semiconductor regions (P⁺) are formed in both sides of the n⁺ type semiconductor region (N⁺) but it is also possible to form the p⁺ type semiconductor regions (P⁺) in both sides before and after the same n⁺ type semiconductor region (N⁺). Namely, it is possible to form the n⁺ type semiconductor region (N⁺) surrounded by the p⁺ type semiconductor region (P⁺).

As shown in FIG. 5B, such varactor diode PN_VD1 is provided with the so-called SOI structure where an embedded insulating layer IS1 (SiO₂) is formed, for example, on the p type semiconductor substrate (supporting substrate) and moreover, a semiconductor layer DF is formed on the IS1. In the case where a plurality of varactor diodes PN_VD1 are formed, each varactor diode PN_VD1 is individually separated with the embedded insulating layer IS1 and the trench isolation insulating layer IS2 (SiO₂) formed to reach the IS1 from the main surface of the semiconductor layer DF.

In the semiconductor layer DF of the varactor diode PN_VD1, the n⁻ type semiconductor region (N⁻) and the p type semiconductor region (P) are sequentially formed toward the main surface of DF from the embedded insulating layer IS1. In the p type semiconductor region (P), the n⁺ type semiconductor region (N⁺) is formed to the central area thereof. This region is connected to a metal wiring layer M1 which becomes the cathode node CD via a barrier layer (CoSi₂) (not illustrated) and a contact layer CNT. Meanwhile, the p⁺ type semiconductor regions (P⁺) are formed in both sides of the n⁺ type semiconductor region (N⁺) holding an insulating layer IS3 formed reaching the p type semiconductor region (P) from the main surface of the DF. This p⁺ type semiconductor region (P⁺) is connected to the metal wiring layer Ml which becomes the anode node AD via the barrier layer (CoSi₂) (not illustrated) and contact layer CNT.

Upon comparison between the example of structure of FIG. 5B and the conventional structure of FIG. 10, an n⁻ type semiconductor region (N⁻) and a p type semiconductor region (P) are provided between an n⁺ type semiconductor region (N⁺) corresponding to the cathode node CD and the embedded insulating layer IS1. The AFC voltage is impressed to the n⁺ type semiconductor region (N⁺) connected to the cathode node CD, while the ground voltage GND to the p type semiconductor region (P) connected to the anode node AD. Accordingly, noise transferred via the embedded insulating layer IS1 from the semiconductor substrate SUB is attenuated by a high resistance of the n-type semiconductor region (N⁻) and a pn junction between the n-type semiconductor region (N⁻) and the p type semiconductor region (P). Moreover, such noise is further shielded with the ground voltage GND of the p type semiconductor region (P).

In addition, the portion (M1, CNT, N⁺) corresponding to the cathode node CD is held with the portions corresponding to the anode node AD (M1, CNT, P⁺). Therefore, noise transferred in the lateral direction with the metal wiring layer on the semiconductor layer DF, for example, is also shielded with the ground voltage GND of the anode nodes ADs provided in both sides of the cathode node CD. As explained above, since the cathode node CD is shielded in both vertical and horizontal directions, it is not easily influenced by noise and the capacitance value set by the AFC voltage can always be maintained stably. Accordingly, the reference oscillation signal frequency can be set in higher accuracy and stable communication process can always be realized.

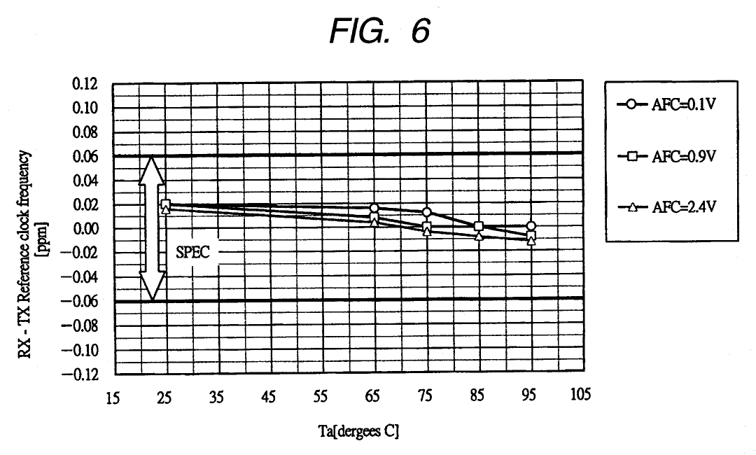

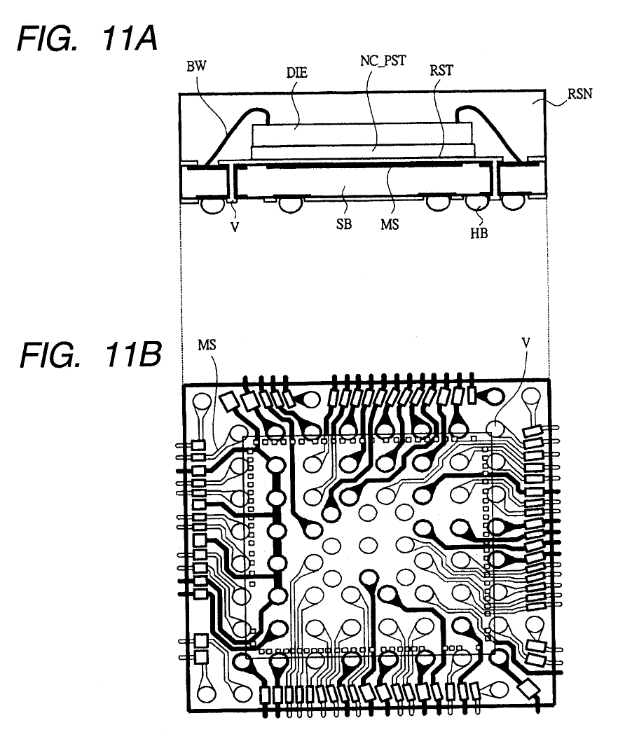

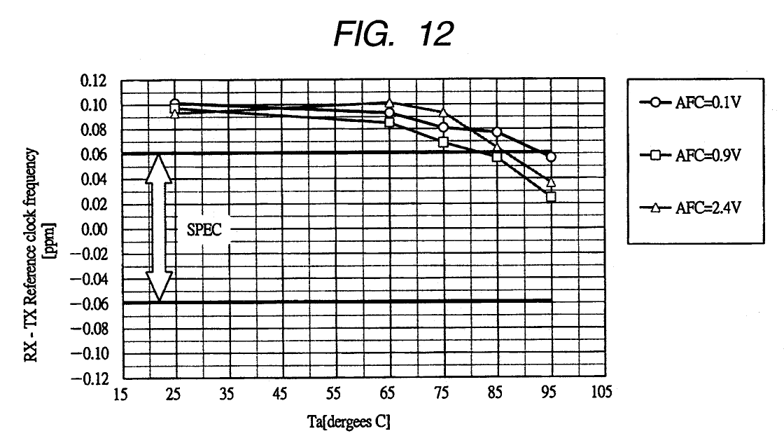

FIG. 6 is a graph showing the evaluation result of the reference frequency of the digital crystal-controlled oscillating circuit under the condition that the front-end circuit comprising the varactor diode of FIG. 5B is sealed in the package of FIG. 11A. FIG. 6 shows, like the FIG. 12 explained above, temperature on the horizontal axis and absolute value of {(reference frequency during transmitting operation)−(reference frequency during receiving operation) } on the vertical axis. Moreover, evaluation is conducted for three kinds (0.1V, 0.9V, 2.4V) of the AFC control voltages (namely, voltages of the cathode node CD of the varactor diode PN_VD1). As shown in this graph, an error of the reference frequency which has been about 0.1 ppm in the structure of the related art can be reduced to about 0.02 ppm (about 0.52 Hz for 26 MHz) by utilizing the structure of FIG. 5B. Accordingly, it is possible to sufficiently attain the accuracy within the range of ±0.06 ppm which are more desirable to assure reliable transmission and reception with a base station.

As explained above, stable communication process can be realized by utilizing the semiconductor device of the first embodiment, even when a varactor diode is comprised in the front-end circuit or the like. Particularly, an error of the reference frequency in the transmitting and receiving operations can be reduced to about 0.02 ppm by utilizing the structure of FIG. 5B. Moreover, reduction in size of the radio communication system represented by a mobile phone system can be realized by comprising a varactor diode into a front-end circuit or the like.

### Second Embodiment

A semiconductor device disclosed in the second embodiment is formed through modification of the structure of the varactor diode shown in FIG. 5B.

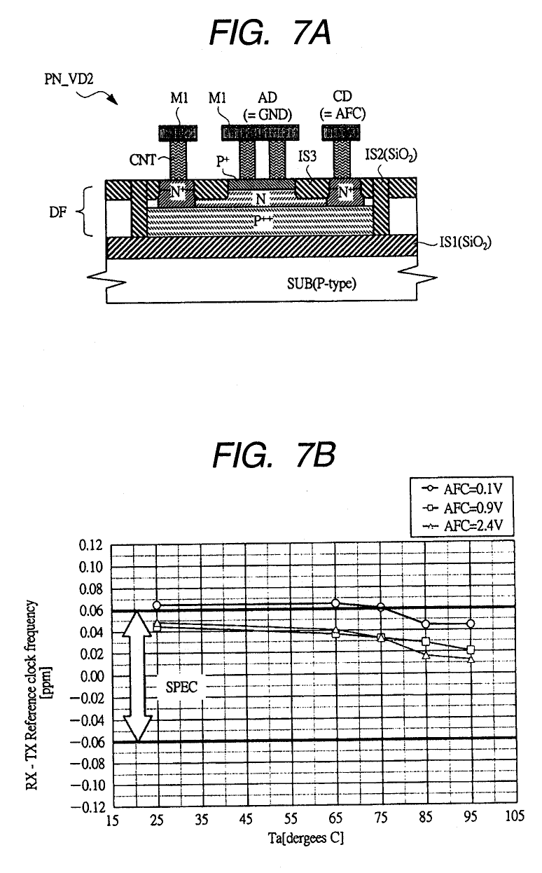

FIGS. 7A and 7B are a diagrams showing a modification example of the varactor diode of FIG. 5B in the semiconductor device of the second embodiment of the present invention. FIG. 7A is a cross-sectional view and FIG. 7B is a graph showing evaluation result. The varactor diode PN_VD2 of FIG. 7A is different from the varactor diode PN_VD1 of FIG. 5B in the arrangement of the anode node AD and cathode node CD and conductivity type of each semiconductor region corresponding to such arrangement. Only difference from the structure of FIG. 5B will be explained below.

In the varactor diode PN_VD2 of FIG. 7A, the p⁺⁺ type semiconductor region (P⁺⁺), and n type semiconductor region (N) are sequentially formed toward the main surface of the semiconductor layer DF from the embedded insulating layer IS1. In the n type semiconductor region (N), the p⁺ type semiconductor region (P⁺) is formed at the central area thereof and this region is connected to the metal wiring layer M1 which becomes the anode node AD via the barrier layer (CoSi₂) (not illustrated) and the contact layer CNT. Meanwhile, the n⁺ type semiconductor region (N⁺) is formed in both sides of the p⁺ type semiconductor region (P⁺) holding the insulating layer IS3 formed to reach the n type semiconductor region (N) from the main surface of the semiconductor layer DF. This n⁺ type semiconductor region (N⁺) is connected to the metal wiring layer M1 which becomes the cathode node CD via the barrier layer (CoSi₂) (not illustrated) and the contact layer CNT.

In such a structure, noise transferred from the semiconductor substrate (supporting substrate) SUB via the embedded insulating layer IS1 is then transferred to the n⁺ type semiconductor region (N⁺) corresponding to the cathode node CD via the p⁺⁺ type semiconductor region (P⁺⁺). Accordingly, it is expected that noise can be alleviated with a capacitance or the like of the pn junction as much because noise is transferred through this p⁺⁺ type semiconductor region (P⁺+) in comparison with the structure of related art of FIG. 10. Actually, as a result of evaluation of the reference frequency as in the case of FIG. 6, an error of about 0.06 ppm is generated as shown in FIG. 7B. As this result suggests, more stable communication process can be realized in comparison with the structure of the related art of FIG. 10. The structure of FIG. 5B shows more excellent effects, because the p⁺⁺ type semiconductor region (P⁺⁺) is not connected to the ground voltage GND and both sides of the cathode node CD are not held by the anode node AD in the structure of FIG. 7A.

### Third Embodiment

The semiconductor device disclosed in the third embodiment is formed through modification of the varactor diode shown in FIG. 5B like the second embodiment.

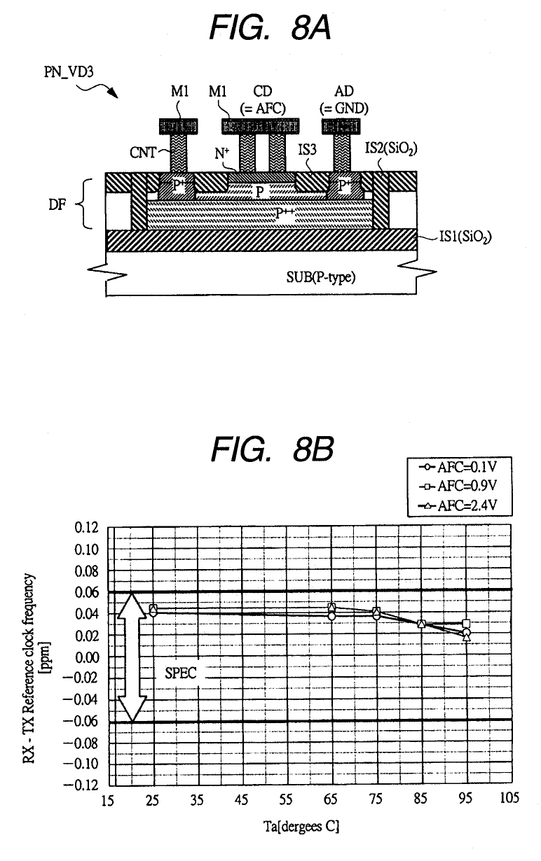

FIGS. 8A and 8B are diagrams showing another embodiment of the varactor diode of FIG. 5B in the semiconductor device of the third embodiment of the present invention. FIG. 8A is a cross-sectional view and FIG. 8B is a graph showing the evaluation result. The varactor diode PN_VD3 of FIG. 8A is identical in the arrangement and structure of the anode node AD and cathode node CD in comparison with the varactor diode PN_VD1 of FIG. 5B. Difference from the structure of FIG. 5B is only that the n⁻type semiconductor region (N⁻) on the embedded insulating layer IS1 in FIG. 5B is changed to the p⁺⁺ type semiconductor region (P⁺⁺) in FIG. 8A.

In the structure explained above, noise transferred via the embedded insulating layer IS1 from the semiconductor substrate SUB is further transferred to the n⁺ type semiconductor region (N⁺) corresponding to the cathode node CD via the p⁺⁺ type semiconductor region (P⁺⁺) and the p type semiconductor region (P). Accordingly, as a result of comparison with the structure of the related art of FIG. 10, noise is transferred to the cathode node CD via the p++ type semiconductor region (P++) and this region can shield the noise and thereby it is coupled to the ground voltage GND through connection with the anode node AD.

Actually, as a result of evaluation of the reference frequency as in the case of FIG. 6, an error of the reference frequency has been reduced to about 0.04 ppm as shown in FIG. 8B. Accordingly, more stable communication process can be realized in comparison with the conventional structure of FIG. 10 and the structure of FIG. 7A. In comparison of the structure of FIG. 8A with the structure of FIG. 5B, the high resistance n⁻type semiconductor region (N⁻) and the pn junction are provided between the embedded insulating layer IS1 and the n⁺ type semiconductor region (N⁺) corresponding to the cathode node CD in the structure of FIG. 5B. Therefore, the structure of FIG. 5B can provide more sufficient effects.

### Fourth Embodiment

The semiconductor device of the fourth embodiment is mainly characterized in the shape of a package for packaging the front-end circuit F_IC of FIG. 1 explained above.

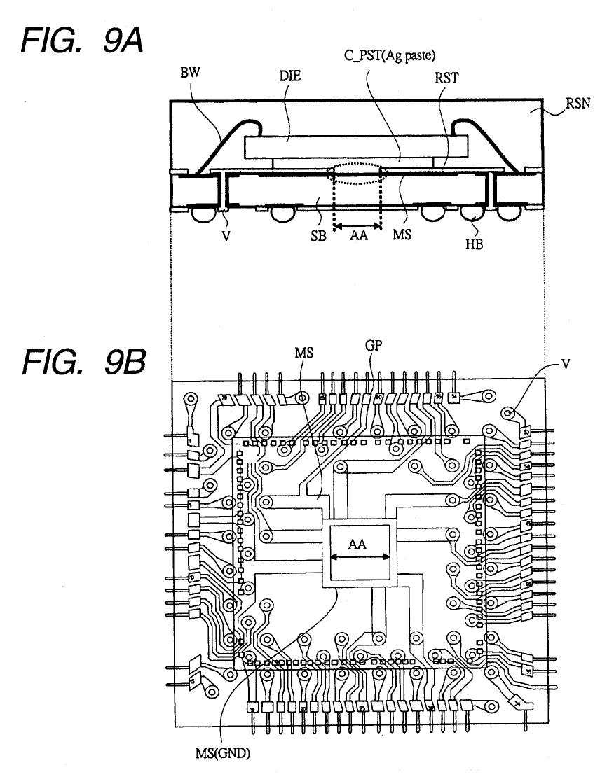

FIGS. 9A and 9B are diagrams showing an example of an external shape of the package of the semiconductor device as the fourth embodiment of the present invention. FIG. 9A is a cross-sectional view of the same semiconductor device and FIG. 9B is a plan view thereof. The front-end circuit F_IC used for the mobile phone system is generally mounted in the package such as BGL and LGA (Land Grid Array) in order to realize high density packaging. Here, the BGA is explained as an example and this embodiment can also be adapted to a package using a wiring substrate with inclusion of the LGA.

The semiconductor device of FIG. 9A is provided with a wiring substrate SB respectively including wiring patterns MS at the front and rear surfaces thereof and the front surface of the substrate SB is coated with resist RST. This resist is removed from a constant region AA corresponding to the central area of the substrate SB with reference to the plan view of the package as shown in FIGS. 9A and 9B. On the front surface of the wiring substrate SB corresponding to the constant region AA, the wiring pattern MS (GND) which becomes the ground voltage GND is formed as shown in FIG. 9B. The wiring pattern MS (GND) is connected, as shown in FIG. 9A, to the wiring pattern MS at the rear surface of substrate SB through the vias and moreover connected to solder balls HBs corresponding to the external ground terminals. In addition, this wiring pattern MS (GND) is provided to the external circumferential portion of the front surface of the substrate SB and is also connected to the ground pins GPs used for the wire bonding for the semiconductor chip DIE.

Meanwhile, a conductive paste material C_PST such as Ag paste is coated on the resist RST and a semiconductor chip DIE corresponding to the front-end circuit F_IC of FIG. 1 is mounted on the conductive paste material. Accordingly, the rear surface of the semiconductor chip DEI is connected, via the conductive paste material C_PST, to the wiring pattern MS (GND) at the front surface of the substrate SB explained above in the constant region AA where the resist RST has been removed. The front surface of the semiconductor chip DIE is provided with a plurality of electrode pads and these pads are adequately connected, with the bonding wires BW, to a plurality of pins provided at the external circumferential portion of the front surface of substrate SB. For example, the electrode pads which become the ground on the front surface of the semiconductor chip DIE are connected to the ground pins GP on the front surface of substrate SB. The semiconductor chip DIE mounted on the wiring substrate SB as explained above is molded with a package resin RSN and thereby packaging is completed.

Here, the semiconductor chip DIE is completed with the SOI structure as shown in FIG. 10. Moreover, the varactor diodes included in this semiconductor chip may be constituted in the structure explained in the first embodiment or in the structure of the related art as shown in FIG. 10. When the shape of package explained above is employed, the semiconductor substrate SUB in the SOI structure is fixed to the ground voltage GND. Therefore, noise transferred via the semiconductor substrate SUB explained above can be reduced. Such noise reduction effect can be attained not only for the part of varactor diode but also for the entire part of the semiconductor chip. Moreover, in this structure, attention is necessary for influence on increase in the wiring density of the wiring substrate SB due to formation of the wiring pattern MS (GND) and reliability of resist RST for breakdown of the resist RST at the area outside of the region AA.

The present invention has been explained more concretely on the basis of the preferred embodiments thereof, but the present invention is not restricted to the preferred embodiments explained above and allows various changes and modifications within the scope not departing from the subject matter thereof.

The semiconductor device of the present invention is based on the technology which may be adapted with particular profits to a semiconductor device for communication use such as the front-end IC or the like in the mobile phone system. Moreover, the semiconductor device of the present invention can also be adapted in the same manner to the semiconductor device for communication use in the radio communication system specified with Bluetooth and IEEE 802.11 or the like. In addition the semiconductor device of the present invention can be adapted as the technology for improving the resistance to noise even for the varactor diodes used in the fields other than communication.

What is claimed is:

1. A semiconductor device comprising:
a semiconductor chip of a structure where a first insulating layer is formed over a supporting substrate and a semiconductor layer is formed over said first insulating layer,
said semiconductor layer being formed with:
a first circuit for generating a reference oscillation signal of a predetermined reference frequency;
a second circuit for generating a local oscillation signal of a frequency equal to constant times of said reference frequency using said reference oscillation signal; and
a frequency converting circuit for synthesizing a transmitting signal or a receiving signal and said local oscillation signal,
wherein a varactor diode for adjusting said reference frequency by changing a voltage of a frequency adjusting node for a reference voltage node is formed to said first circuit of said semiconductor layer, and
wherein said varacotor diode of said semiconductor layer is formed with:
a first semiconductor region of a first conductivity type connected to said frequency adjusting node; and
a second semiconductor region of a second conductivity type opposing to said first conductivity type, formed between said first semiconductor region and said first insulating layer.

2. The semiconductor device according to claim 1,
wherein, at said varactor diode of said semiconductor layer,
a third semiconductor region of said first conductivity type is formed over said first insulating layer,
said second semiconductor region of said second conductivity type is formed over said third insulating layer,
said first semiconductor region of said first conductivity type is formed over said second semiconductor region, and
said second semiconductor region is connected to said reference voltage node.

3. The semiconductor device according to claim 1,
wherein, at said varactor diode of said semiconductor layer,
said second semiconductor region of said second conductivity type is formed over said first insulating layer,
said first semiconductor region of said first conductivity type is formed over said second semiconductor region, and
said second semiconductor region is connected to said reference voltage node.

4. The semiconductor device according to claim 1,
wherein, at said varactor diode of said semiconductor layer,
said second semiconductor region of said second conductivity type is formed over said first insulating layer,
said first semiconductor region of said first conductivity type is formed over said second semiconductor region,
a fourth semiconductor region of said second conductivity type is formed over said first semiconductor region, and
said fourth semiconductor region is connected to said reference voltage node.

5. The semiconductor device according to claim 1,
wherein said plurality of varactor diodes are formed, and
wherein said plurality of varactor diodes are respectively separated by said first insulating layer and a plurality of trench isolation insulating layers formed to reach said first insulating layer from the main surface of said semiconductor layer.

6. The semiconductor device according to claim 2,
wherein said third semiconductor region is lower in the impurity concentration than said first semiconductor region.

7. The semiconductor device according to claim 2,
wherein when said varactor diode of said semiconductor layer is viewed as a plan view thereof from the main surface side, said reference voltage nodes connected to said second semiconductor region are allocated in both sides of said frequency adjusting node connected to said first semiconductor region.

8. The semiconductor device according to claim 7,
wherein said frequency adjusting node corresponds to a cathode node, and
wherein said reference voltage node corresponds to an anode node, and supplied with the ground voltage.

9. A semiconductor device comprising:
a semiconductor chip of a structure where a first insulating layer is formed over a supporting substrate and a semiconductor layer is formed over said first insulating layer,
said semiconductor layer being formed with:
a crystal-controlled oscillating circuit for generating the reference oscillation signal of the predetermined reference frequency;
a second circuit for generating a local oscillation signal of the frequency equal to constant times of said reference frequency using said reference oscillation signal; and
a frequency converting circuit for synthesizing a transmitting signal or a receiving signal and said local oscillation signal,
wherein a varactor diode which is capable of adjusting said reference frequency with a voltage value applied thereto is formed to said crystal-controlled oscillating circuit of said semiconductor layer.

10. The semiconductor device according to claim 9,
wherein said plurality of varactor diodes are formed, and
wherein said plurality of varactor diodes are isolated from each other by said first insulating layer and a plurality of trench isolation insulating layers formed to reach said first insulating layer from the main surface of said semiconductor layer.

11. The semiconductor device according to claim 9,
wherein the rear surface of said supporting substrate is connected to the ground voltage.

12. The semiconductor device according to claim 11,
wherein said semiconductor chip is mounted to a package provided with a wiring substrate,
wherein a plurality of wiring patterns are provided over the front surface of said wiring substrate,
wherein a part of said plurality of wiring patterns is formed as a wiring pattern for ground voltage connected to an external terminal being set to the ground voltage, and
wherein the rear surface of said supporting substrate is connected to said wiring pattern for ground voltage at the front surface of said wiring substrate via a conductive paste.

13. The semiconductor device according to claims 12,
wherein said semiconductor chip is mounted to a BGA package.
